(19) United States
(12) Patent Application Publication
(10) Pub. No.: US 2024/0030387 A1
(43) Pub. Date: Jan. 25, 2024

(54) LIGHT-EMITTING DEVICE AND METHOD FOR MANUFACTURING THE SAME

(71) Applicant: TIANJIN SANAN OPTOELECTRONICS CO., LTD., Tianjin (CN)

(72) Inventors: Zhiwei WU, Tianjin (CN); Yanyun WANG, Tianjin (CN); Weiping XIONG, Tianjin (CN); Liguo ZHANG, Tianjin (CN); Huanshao KUO, Tianjin (CN)

(21) Appl. No.: 18/348,893

(22) Filed: Jul. 7, 2023

(30) Foreign Application Priority Data
Jul. 22, 2022 (CN) 202210874460.1

(51) Int. Cl. H01L 33/40; H01L 33/00

(52) U.S. Cl. CPC H01L 33/40; H01L 33/0075

(57) ABSTRACT

A light-emitting includes an epitaxial structure, a diffusion blocking layer, an ohmic contact layer, a first electrode, and a second electrode. The epitaxial structure includes a first semiconductor layer, an active layer, and a second semiconductor layer disposed sequentially in such order. The diffusion blocking layer is disposed on a surface of the first semiconductor layer opposite to the active layer. The ohmic contact layer is disposed on a surface of the diffusion blocking layer opposite to the first semiconductor layer. The first electrode is disposed on a surface of the ohmic contact layer opposite to the diffusion blocking layer and is electrically connected to the first semiconductor layer. The second electrode is disposed on a surface of the second semiconductor layer adjacent to the active layer and is electrically connected to the second semiconductor layer. A method for manufacturing the light-emitting device is also provided.

### CROSS-REFERENCE TO RELATED APPLICATION

This application claims priority to Chinese Invention Patent Application No. 202210874460.1, filed on Jul. 22, 2022, the disclosure of which is incorporated herein by reference in its entirety.

### FIELD

The disclosure relates to a semiconductor device, and more particularly to a light-emitting device and a method for manufacturing the same.

### BACKGROUND

With the development of light-emitting diode (LED) chips and related products, Mini LED chips and Micro LED chips are recognized for their small size, high integration, fast response rate, good thermal stability, and low energy consumption, and are increasingly being commercialized.

Currently, a majority of the LED chips are packaged using flip chip technology. Electrodes in the LED chips are usually made of metals or metal alloy materials, which are fused at high temperature to form an ohmic contact with a semiconductor region, and the electrodes experience mainly mutual diffusion and phase transition during an alloying process. However, voids generally exist at the thus formed ohmic contact, making the electrodes easy to fall off. On the other hand, a deeper diffusion may lead to leakage, which may seriously affect overall reliability of the LED chips.

Therefore, reducing or preventing the diffusion between the metals in the electrodes and the semiconductor region from being too deep so as to enhance the reliability of the LED chips and ensure a stable optoelectronic performance of the chips is one of challenges that needs to be addressed.

### SUMMARY

Therefore, an object of the disclosure is to provide a light-emitting device that can alleviate at least one of the drawbacks of the prior art.

According to one aspect of the disclosure, a light-emitting device includes an epitaxial structure, a diffusion blocking layer, an ohmic contact layer, a first electrode, and a second electrode. The epitaxial structure includes a first semiconductor layer, an active layer, and a second semiconductor layer disposed sequentially in such order. The diffusion blocking layer is disposed on a surface of the first semiconductor layer opposite to the active layer. The ohmic contact layer is disposed on a surface of the diffusion blocking layer opposite to the first semiconductor layer. The first electrode is disposed on a surface of the ohmic contact layer opposite to the diffusion blocking layer and is electrically connected to the first semiconductor layer. The second electrode is disposed on and is electrically connected to the second semiconductor layer.

According to another aspect of the disclosure, a method for manufacturing a light-emitting device includes the following steps: sequentially forming an ohmic contact layer, a diffusion blocking layer, a first semiconductor layer, an active layer, and a second semiconductor layer on a growth substrate so as to form a laminate structure on the growth substrate; bonding the laminate structure to a supporting substrate through a bonding layer with the second semiconductor layer facing the bonding layer, and removing the growth substrate; forming an insulation layer on the ohmic contact layer and the diffusion blocking layer, the insulation layer having two through holes; and forming a first electrode and a second electrode on the insulation layer such that the first electrode and the second electrode respectively extend into the through holes to electrically connect to the first semiconductor layer and the second semiconductor layer, respectively.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a cross-sectional schematic view illustrating a first embodiment of a light-emitting device according to the disclosure.

FIG. 2 is a cross-sectional schematic view illustrating a variation of the first embodiment of the light-emitting device according to the disclosure.

FIG. 3 is a cross-sectional schematic view illustrating a second embodiment of a light-emitting device according to the disclosure.

FIG. 4 is a cross-sectional schematic view illustrating a third embodiment of a light-emitting device according to the disclosure.

FIG. 5 is a flow chart illustrating a method for manufacturing of a light-emitting device according to the disclosure.

FIGS. 6 to 11 are schematic diagrams illustrating the method shown in FIG. 5.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

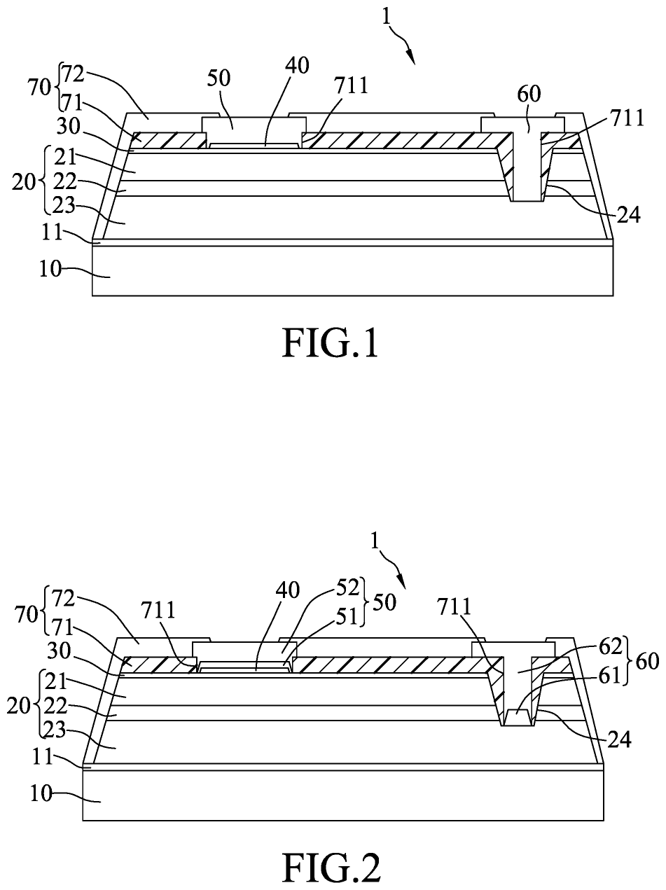

Referring to FIG. 1, a light-emitting device 1 according to the disclosure includes an epitaxial structure 20, a diffusion blocking layer 30, an ohmic contact layer 40, a first electrode 50, and a second electrode 60. The epitaxial structure includes a first semiconductor layer 21, an active layer 22, and a second semiconductor layer 23 disposed sequentially in such order in a stacking direction. The diffusion blocking layer 30 is disposed on a surface of the first semiconductor layer 21 opposite to the active layer 22. The ohmic contact layer 40 is disposed on a surface of the diffusion blocking layer 30 opposite to the first semiconductor layer 21. The first electrode 50 is disposed on a surface of the ohmic contact layer 40 opposite to the diffusion blocking layer 30 and is electrically connected to the first semiconductor layer 21. The second electrode 60 is disposed on a surface of the second semiconductor layer 23 and is electrically connected to the second semiconductor layer 23.

The epitaxial structure 20 is disposed on a supporting substrate 10. The supporting substrate 10 may be a conductive substrate or a non-conductive substrate, or a transparent substrate or a non-transparent substrate. In the embodiment shown in FIG. 1, the supporting substrate 10 is a transparent non-conductive substrate (or referred to as a base). The supporting substrate 10 may be made of a conductive or a semiconductor material. For example, the supporting substrate 10 may be made of at least one of silicon carbide (SiC), silicon (Si), magnesium oxide (MgO), lithium gallium oxide (LiGaO₂), gallium nitride (GaN), and combinations thereof.

The supporting substrate 10 may be made of a transparent material that provides sufficient mechanical strength to support the epitaxial structure 20, and is able to transmit light emitted from the epitaxial structure 20. Alternatively, the supporting substrate 10 may be made of a material that is optically transparent with respect to the light emitted from the active layer 22. In addition, the supporting substrate 10 may be made of a chemically stable material having excellent moisture resistance, such as a material not containing corrosion-prone elements, e.g., aluminum or the like. The supporting substrate 10 may be a substrate having a thermal expansion coefficient close to that of the epitaxial structure 20, such as GaP, SiC, sapphire, or transparent glass with good thermal conductivity.

The epitaxial structure 20 may be formed on a growth substrate 100 by metal-organic chemical vapor deposition (MOCVD), molecular beam epitaxy (MBE), hydride vapor phase deposition (HYPE), physical vapor deposition (PVD), ion plating, etc. The growth substrate 100 may be made of, but is not limited to, at least one of sapphire (Al₂O₃), SiC, GaAs, GaN, ZnO, GaP, InP, Ge, and combinations thereof. In this embodiment, the growth substrate 100 is made of GaAs.

The light-emitting device 1 may further include a bonding layer 11 disposed between the supporting substrate 10 and the epitaxial structure 20. After the epitaxial structure 20 is formed on the growth substrate 100, the epitaxial structure 20 is generally transferred and bonded to the supporting substrate 10 by the bonding layer 11. The bonding layer 11 may be made of a light-transmissive material or a transparent material. The bonding layer 11 may be a single-layered or a multi-layered structure, may be made of a conductive or an insulating material, and may be made of a transparent or a non-transparent material. In certain embodiments, the bonding layer 11 is a composite multi-layered structure including a conductive bonding layer and a non-conductive bonding layer that is closer to the supporting substrate 10 than the conductive bonding layer.

The epitaxial structure 20 may emit light with a specific peak emission wavelength, such as blue light, green light, red light, infrared light, violet light, or ultraviolet light. In the present embodiment, the epitaxial structure 20 emitting red light or infrared light is used as an example for illustration. In the embodiment shown in FIG. 1, the first semiconductor layer 21 in the epitaxial structure 20 is an N-type semiconductor layer, which may provide electrons to the active layer 22 when voltage is applied. In some embodiments, the first semiconductor layer 21 may include N-type doped AlGaInP, AlGaAs, or other suitable materials.

The active layer 22 may be a quantum well (QW) structure, which may either be a single quantum well structure or a multiple quantum well (MQW) structure. In some embodiments, the active layer 22 may be a multiple quantum well structure which includes alternatively stacked quantum well layers and quantum barrier layers. The quantum barrier layers may be made of GaN or AlGaN. In some embodiments, the active layer 22 may include a multiple quantum well structure that has alternately stacking GaN/AlGaN layers, InAlGaN/InAlGaN layers, InGaN/AlGaN layers, InGaAS/AlGaAs layers, GaInP/AlGaInP layers, or GaInP/AlInP layers. An enhanced light-emitting efficiency of the active layer 22 may be achieved by changing depth of the quantum wells, quantity, thickness and/or other features of the paired quantum well layers and quantum barrier layers in the active layer 22.

In the embodiment shown in FIG. 1, the second semiconductor layer 23 in the epitaxial structure 20 is a P-type semiconductor layer, which may provide holes for the active layer 22 when power is turned on. In some embodiments, the second semiconductor layer 23 includes a P-type doped nitride layer, a phosphide layer, or an arsenide layer. The P-type doped nitride layer, phosphide layer, or arsenide layer may include one or more P-type dopants of group II materials. The P-type dopant may be one of Mg, Zn, Be, or combinations thereof. The second semiconductor layer 23 may be a single-layered structure or a multi-layered structure. Layers of the multi-layered structure may have different compositions. The epitaxial structure 20 is not limited to have a configuration as those described above, and may have different configurations according to actual requirements.

In the embodiment shown in FIG. 1, the ohmic contact layer 40 and the diffusion blocking layer 30 are formed on the growth substrate 100 in such order before sequential growth of the first semiconductor layer 21, the active layer 22, and the second semiconductor layer 23. In other words, as shown in FIG. 1, the diffusion blocking layer 30 and the ohmic contact layer 40 are sequentially disposed on at least a portion of the surface of the first semiconductor layer 21 opposite to the active layer 22 or the supporting substrate 10. In some embodiments, a projection of the ohmic contact layer 40 on the first semiconductor layer 21 falls within a projection of the diffusion blocking layer 30 on the first semiconductor layer 21. That is to say, the ohmic contact layer 40 is disposed on and occupies a portion of a surface of the diffusion blocking layer 30 opposite to the first semiconductor layer 21. In addition, the ohmic contact layer 40 is electrically connected to the first electrode 50.

In the light-emitting device 1 according to the embodiments of the present disclosure, the first electrode 50 and the second electrode 60 are spaced apart from each other. The first electrode 50 is disposed on the surface of the ohmic contact layer 40 opposite to the diffusion blocking layer 30 and is electrically connected to the first semiconductor layer 21 of the epitaxial structure 20. The second electrode 60 is disposed on a surface of the second semiconductor layer 23 of the epitaxial structure 20 and is electrically connected to the second semiconductor layer 23. The first electrode 50 and the second electrode 60 may be made of a metal material, for example, chromium (Cr), titanium (Ti), tungsten (W), gold (Au), aluminum (Al), indium (In), tin (Sn), nickel (Ni), rhodium (Rh), platinum (Pt), germanium (Ge), beryllium (Be), gold-germanium (AuGe), gold-germanium-nickel (AuGeNi), beryllium-gold (BeAu), gold-zinc (AuZn), or combinations thereof. The first electrode 50 and the second electrode 60 may be a single-layered structure or a laminated structure which, for example, may be made of Ti/Au, Ti/Pt/Au, Cr/Au, Cr/Pt/Au, Ni/Au, Ni/Pt/Au, Cr/Al/Cr/Ni/Au, Au/AuGeNi/Au or Au/BeAu/Au, etc.

The projection of the ohmic contact layer 40 on the epitaxial structure 20 falls within a projection of the first electrode 50 on the epitaxial structure 20. That is to say, a surface of the first electrode 50 that is adjacent to the ohmic contact layer 40 is greater than the surface of the ohmic contact layer opposite to the diffusion blocking layer 30, and is smaller than a surface of the diffusion blocking layer 30 that is adjacent to and covers the surface of the first semiconductor layer 21 opposite to the active layer 22. With such design of the light-emitting device 1, when the first electrode 50 is being fused at high temperature, the diffusion blocking layer 30 may block or prevent the diffusion of the metal materials between the first electrode 50 and the first semiconductor layer 21 from being too deep. Furthermore, electrical conduction between the first electrode 50 and the first semiconductor layer 21 may be improved because of the ohmic contact layer 40, thus overall reliability of the light-emitting device 1 is enhanced.

To more effectively prevent the diffusion of the metal materials between the first electrode 50 and the first semiconductor layer 21 from being too deep so as to enhance overall performance of the light-emitting device 1, the diffusion blocking layer 30 has a thickness in the stacking direction ranging from 50 Å to 500 Å. Such thickness of the diffusion blocking layer 30 may ensure the prevention of the diffusion of the metal materials between the electrodes and the semiconductor layer from being too deep, performance of electrical conduction between the first electrode 50 and the first semiconductor layer 21, and proper control of overall thickness of the light-emitting device 1. The diffusion blocking layer 30 may be made of a group III-V semiconductor material, but not limited thereto, so that the diffusion blocking layer 30 may have good electrical conductivity. The diffusion blocking layer 30 may have a composition that is represented by Ga_{X}In_{(1-X)}P, and 0≤X≤1. In certain embodiments, the diffusion blocking layer 30 has a composition that is represented by Ga_{0.5}In_{0.5}P which provides a good prevention of the diffusion of the metals between the first electrode and the first semiconductor layer 21 from being too deep.

Typically, P-type and N-type semiconductor regions of a conventional light-emitting device have a stepped configuration, so that a height difference may exist between a P electrode and an N electrode. If the height difference between the P electrode and the N electrode becomes too great, abnormalities of manufactured products, such as tilting, wire-peeling, and cracking due to metal stress caused by pushing and pulling during die bonding may occur, thereby affecting the overall optoelectronic performance of the chip.

Referring to FIG. 1, the first electrode 50 may be an N electrode, and the second electrode 60 may be a P electrode, or vice versa. In some embodiments, each of the first electrode 50 and the second electrode 60 is a metal electrode, and an upper surface of the first electrode 50 is flush with an upper surface of the second electrode 60. In the embodiment shown in FIG. 1, the upper surfaces of the first electrode 50 and the second electrode 60 of the light-emitting device 1 are flush with each other, and there is almost no height difference between the first electrode 50 and the second electrode 60. Such arrangement may reduce abnormalities of manufactured products, such as tilting, wire-peeling and cracking caused by the pushing and pulling during die bonding, and therefore may improve the optoelectronic performance of the light-emitting device 1. Particularly, when the light-emitting device 1 is small in size, the flush alignment between the P electrode and the N electrode provides a significant effect on the enhancement or improvement of the overall light-emitting performance of the light-emitting device 1. The light-emitting device 1 may be a small-sized light-emitting device that has a grain size of no greater than 300 μm, such as a Mini LED and a Micro LED.

Each of the first electrode 50 and the second electrode 60 may include a contact electrode and an electrode pad. In FIG. 1, only the electrode pads of the first electrode 50 and the second electrode 60 are exemplarily illustrated. In FIG. 2, both of the contact electrodes and the electrode pads are exemplarily illustrated. As shown in FIG. 2, the first electrode 50 includes a first contact electrode 51 and a first electrode pad 52 formed on the first contact electrode 51, and the second electrode 60 includes a second contact electrode 61 and a second electrode pad 62 formed on the second contact electrode 61. The electrode pads of the first electrode 50 and the second electrode 60 are used for wire bonding or soldering, so as to facilitate the light-emitting device 1 being electrically connected to an external power source or an external electronic element. In some embodiments, the first electrode 50 and/or the second electrode 60 may further include finger structures (not shown) as part of the contact electrodes.

In some embodiments, the light-emitting device 1 according to the present disclosure may further include an insulation structure 70 for providing insulation protection to the epitaxial structure 20 and the first and second electrodes 50, 60, so as to ensure that the light-emitting device 1 has good optoelectronic performance. The insulation structure 70 may be made of an insulating material such as silicon dioxide.

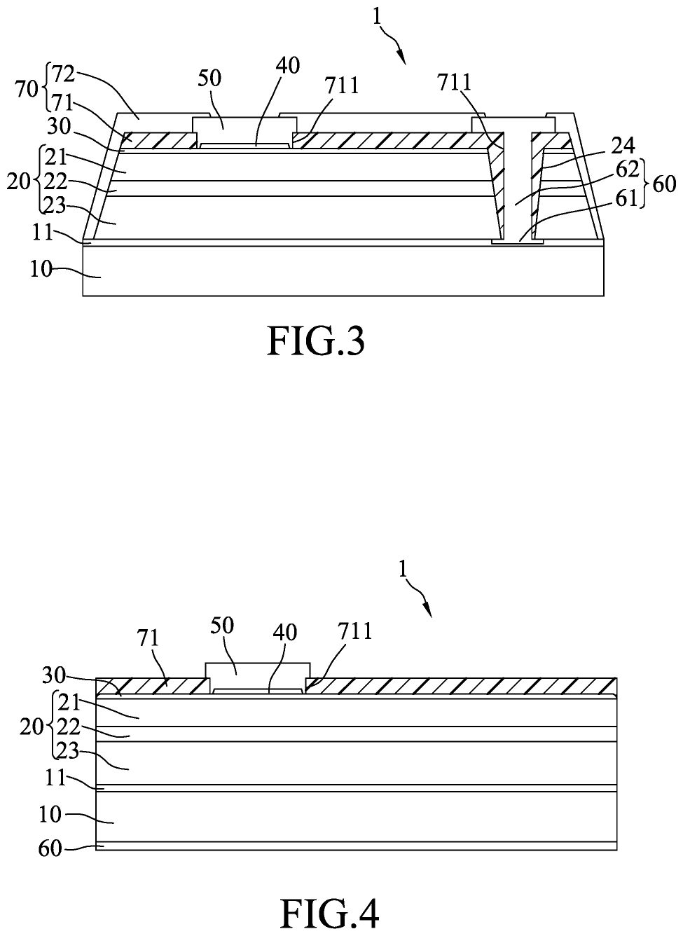

As shown in FIGS. 1 and 2, the epitaxial structure 20 includes a recess 24 that is defined by an inner sidewall and that exposes a surface of the second semiconductor layer 23 that electrically connects to the second electrode 60. In some embodiments, the insulation structure 70 may include a first insulation layer 71 and a second insulation layer 72 (see FIG. 2). The first insulation layer 71 is formed on the epitaxial structure 20, and covers a portion of the surface of the diffusion blocking layer 30 opposite to the active layer 22 and the inner sidewall which defines the recess 24 to provide insulation protection. In certain embodiments, the first insulation layer 71 has through holes 711, and the first electrode 50 and the second electrode 60 extend into the through holes 711 to electrically connect to the first and second semiconductor layers 21, 23, respectively. In some embodiments, the ohmic contact layer 40 is exposed from the first insulation layer 71 through the through hole 711 that corresponds to the first electrode 50 and is spaced apart from the first insulation layer 71 by a gap, and the first electrode 50 extends into the gap to contact the diffusion blocking layer 30. Similarly, the second semiconductor layer 23 is exposed from the first insulation layer 71 through the through hole 711 that corresponds to the second electrode 60, and the second electrode 60 extends into the through hole 711 to contact the second semiconductor layer 23. In the embodiment shown in FIG. 3, the recess 24 extends through the epitaxial structure 20 and into the bonding layer 11 so as to expose a bottom surface of the second semiconductor layer 23 that is opposite to the active layer 22. In this embodiment, the second contact electrode 61 of the second electrode 60 is formed on the exposed bottom surface of the second semiconductor layer 23 opposite to the active layer 22, and the second electrode pad 62 is formed on the second contact electrode 61 and extends through the through hole 711 to electrically connect to another device.

In some embodiments of the present disclosure, the second insulation layer 72 is formed on the first insulation layer 71, and has openings so that a portion of the upper surface of the first electrode 50 opposite to the epitaxial structure 20 and a portion of the upper surface of the second electrode 60 opposite to the epitaxial structure 20 are exposed. The second insulation layer 72 at least covers a portion of the surface of the first insulation layer 71 opposite to the diffusion blocking layer 30 and an outer sidewall of the epitaxial structure 20 to provide insulation protection so as to ensure the overall optoelectronic performance of the light-emitting device 1. The exposed upper surface of the first electrode 50 is flush with the exposed upper surface of the second electrode 60, which may reduce or eliminate adverse effects of the height difference between the first electrode 50 and the second electrode 60 on the overall performance of the light-emitting device 1. In the embodiments shown in FIGS. 1 to 3, the first electrode 50 and the second electrode 60 are disposed on the same side of the epitaxial structure 20.

FIG. 4 illustrates another embodiment of the light-emitting device 1 according to the present disclosure, which is generally similar to the previous embodiment and also includes the epitaxial structure 20, the diffusion blocking layer 30, the ohmic contact layer 40, the first electrode 50, and the second electrode 60. In this embodiment, the first electrode 50 and the second electrode 60 are disposed on opposite sides of the epitaxial structure 20 (i.e., a vertical type light-emitting device 1). Moreover, in this embodiment, the insulation structure 70 may only include the first insulation layer 71, i.e., the second insulation layer 72 may be dispensed with. In this embodiment, the first insulation layer 71 is formed on the epitaxial structure 20, and at least covers a portion of the surface of the diffusion blocking layer 30 opposite to the active layer 22 to provide insulation protection, thereby ensuring the overall optoelectronic performance of the light-emitting device 1. The first insulation layer 71 may be provided with a through hole 711. The first electrode 50 extends through the through hole 711 to electrically connect to the first semiconductor layer 21.

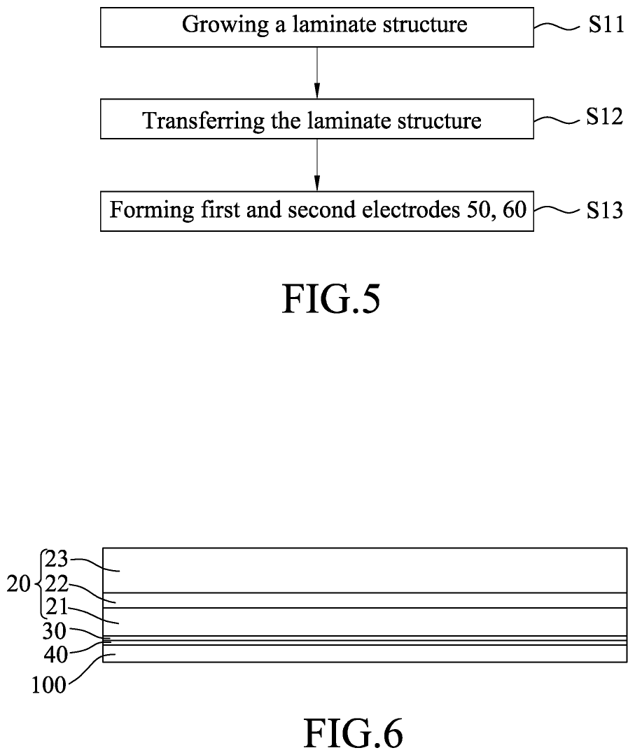

FIG. 5 is a flow chart illustrating a manufacturing method of the light-emitting device 1 according to the disclosure. The method and processes for manufacturing the light-emitting device 1 according to the disclosure are not limited to what is shown in FIG. 5. The processes, in the flow chart of FIG. 5, for manufacturing the light-emitting device 1 of the embodiment of FIG. 1 or FIG. 2 are described below.

The method for manufacturing the light-emitting device 1 may include steps: growing a laminate structure (Step S11), transferring the laminate structure (Step S12), and forming the first and second electrodes 50, 60 (Step S13). Herein, the light-emitting device 1 radiating red light or infrared light is used as an example in describing the manufacturing method of the disclosure.

Step S11: Growing the Laminate Structure

As shown in FIG. 6, the ohmic contact layer 40, the diffusion blocking layer 30, the first semiconductor layer 21, the active layer 22, and the second semiconductor layer 23 are sequentially grown in the stacking direction on the growth substrate 100 so as to form the laminate structure on the growth substrate 100.

In the illustrated example, the growth substrate 100 is a GaAs substrate. The ohmic contact layer 40 is made of a GaAs material. The diffusion barrier layer 30 is made of a semiconductor material of Group III-V. As mentioned above, in certain embodiments, the diffusion barrier layer 30 has the composition that is represented by GaₓIn₍₁₋ₓ₎P, and 0≤X≤1. In certain embodiments, the thickness of the diffusion barrier layer 30 in the stacking direction ranges from 50 Å to 500 Å. The first semiconductor layer 21 is an N-type semiconductor layer, and the second semiconductor layer 23 is a P-type semiconductor layer.

Step S12: Transferring the Laminate Structure

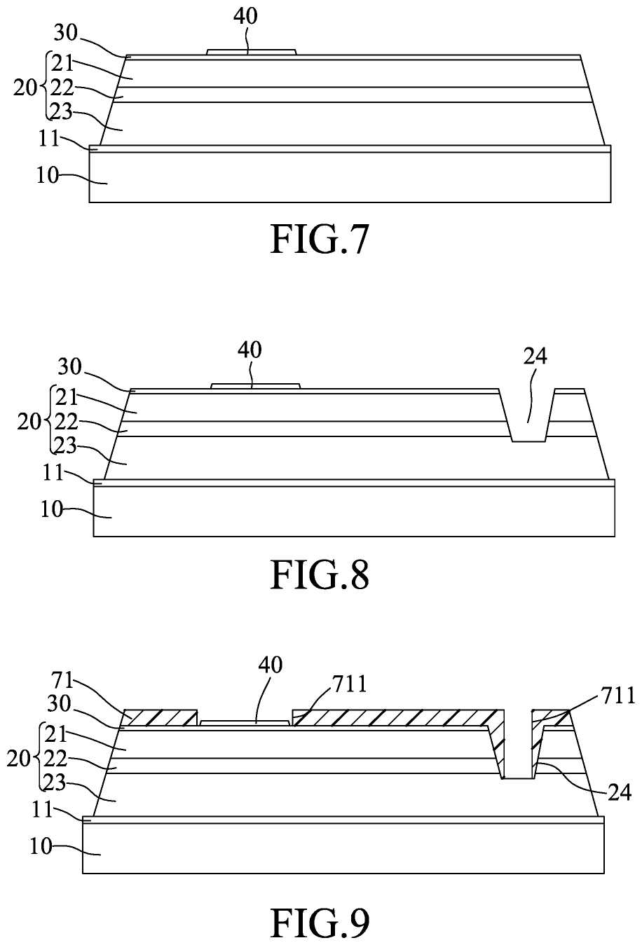

As shown in FIG. 7, the laminate structure is bonded to the supporting substrate 10 through the bonding layer 11 with the second semiconductor layer 23 facing the bonding layer 11, and the growth substrate 100 is removed. The ohmic contact layer 40 is also patterned in this step. Specifically, the bonding layer 11 is formed on the second semiconductor layer 23 of the laminate structure through a deposition process. The resulting bonding layer 11 is then planarized through polishing to ensure that the bonding layer 11 has a flat or planar contact surface for bonding to another substrate (e.g., the supporting substrate 10), thus ensuring that the overall optoelectronic performance of the light-emitting device 1 is not affected by the transfer of the laminate structure. The bonding layer 11 may be made from a transparent material.

The supporting substrate 10 may be a metal substrate or other substrate that may provide support for the laminate structure, and the material of which may be selected and determined according to the actual requirements of the light-emitting device 1. As an example, the supporting substrate 10 is a transparent substrate. The second semiconductor layer 23 (e.g. a P layer) of the laminate structure is bonded to the supporting substrate 10 through the bonding layer 11. After the laminate structure is bonded to the supporting substrate 10, the growth substrate 100 is removed to expose the ohmic contact layer 40. Subsequently, a portion of the ohmic contact layer 40 may be removed by a patterning process using a mask, so that a portion of the diffusion blocking layer 30 may be exposed from the ohmic contact layer 40, and over the first semiconductor layer 21 (e.g. an N layer), the ohmic contact layer 40 (e.g. N—GaAs) disposed on the surface of the diffusion blocking layer 30 opposite to the first semiconductor layer 21 may be used for connection with an electrode (e.g. N electrode).

Step S13: Forming the First and Second Electrodes 50, 60

The first and second electrodes 50, 60 are formed on the transferred laminate structure obtained from Step S12. As shown in FIG. 8, the diffusion blocking layer 30, the first semiconductor layer 21, the active layer 22 and the second semiconductor layer 23 may be processed to form the recess 24 in these layers. The recess 24 is distal from the ohmic contact layer 40 in a direction perpendicular to the stacking direction. The recess 24 penetrates in the stacking direction into the second semiconductor layer 23 through the diffusion blocking layer 30, the first semiconductor layer 21 and the active layer 22 to expose the surface of the second semiconductor layer 23 opposite to the bonding layer 11. The recess 24 may serve as a through hole allowing the second semiconductor layer 23 to connect to a corresponding electrode.

Referring to FIG. 9, the first insulation layer 71 is formed on the ohmic contact layer 40 and the diffusion blocking layer 30, and the first insulation layer 71 covers the recess 24. The first insulation layer 71 has isolated through holes 711. The through holes 711 penetrate through the first insulation layer 71, with one exposing the ohmic contact layer 40 and another one being in spatial communication with the recess 24 to expose the second semiconductor layer 23.

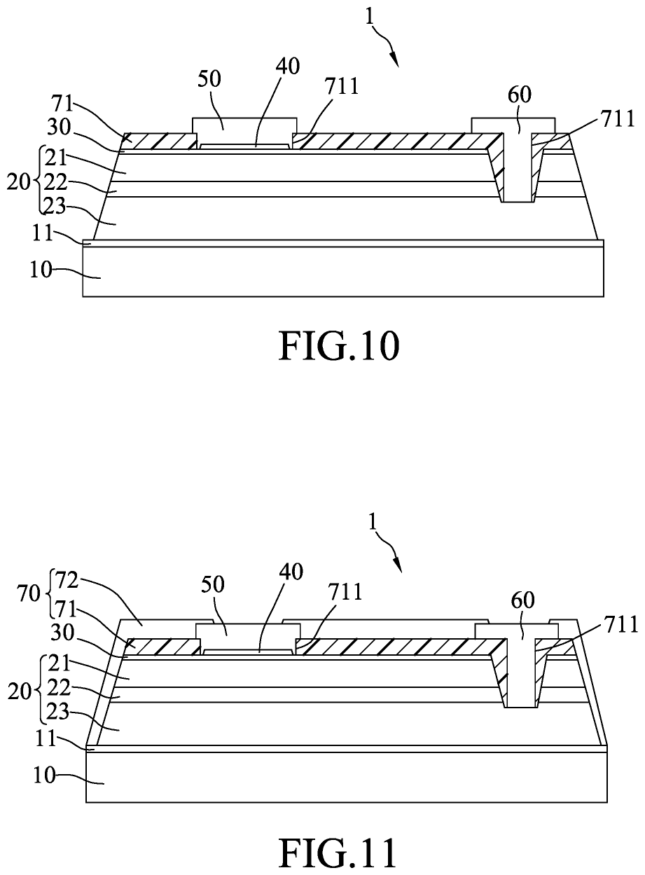

As shown in FIG. 10, the first electrode 50 and the second electrode are formed on the insulation layer 71 and extend into the through hole 711 exposing the ohmic contact layer 40 and the through hole 711 exposing the second semiconductor layer 23, respectively, to electrically connect to the first semiconductor layer 21 and the second semiconductor layer 23, respectively. The first electrode 50 and the second electrode 60 are metal electrodes and may be formed through a process such as evaporation deposition.

The projection of the ohmic contact layer 40 on the first semiconductor layer 21 falls within the projection of the first electrode 50 on the first semiconductor layer 21. The upper surface of the first electrode 50 is flush with the upper surface of the second electrode 60.

In some embodiments, the electrodes may also be formed through other processes. For example, in the manufacturing of the light-emitting device 1 shown in FIG. 3, before transferring the laminate structure (Step S12) and before the bonding layer 11 is deposited on the second semiconductor layer 23 of the laminate structure, the second contact electrode 61 may first be formed on the bottom surface of the second semiconductor layer 23 opposite to the active layer 22. That is to say, the bonding layer 11 is formed after formation of the second contact electrode 61. The subsequent steps for transferring the laminate structure and forming the first electrode 50 and the second electrode 60 (i.e., the second electrode pad 62) may substantially be the same as those processes described above with reference to FIGS. 8, 9, and 10.

Referring back to FIG. 2 in which each of the first and second electrodes 50, 60 includes the contact electrode 51, 61 and the electrode pads 52, 62, in the step of forming the first electrode 50 and the second electrode 60, the first contact electrode 51 and the second contact electrode 61 are first formed respectively, and then the first electrode pad 52 and the second electrode pad 62 are respectively formed on the corresponding one of the first and second contact electrodes 51, 61.

The manufacturing method of the light-emitting device 1 may further include Step S14: forming the second insulation layer 72.

As shown in FIG. 11, the second insulation layer 72 is then formed on the laminate structure and the first and second electrodes 50, 60, and exposes a portion of the upper surfaces of the first electrode 50 and the second electrode 60. The second insulation layer 72 at least covers the outer sidewall of the laminate structure, a portion of the surface of the first insulation layer 71 opposite to the diffusion blocking layer 30, and portions of the upper surfaces of the first electrode 50 and the second electrode 60. The first insulation layer 71 and the second insulation layer 72 together provide effective insulation protection for the laminate structure, thereby ensuring the overall optoelectronic performance of the light-emitting device 1.

The upper surfaces of the first electrode 50 and the second electrode 60 that are respectively exposed from the second insulation layer 72 are flush with each other. That is to say, the first electrode 50 and the second electrode 60 are in a flush arrangement.

In the light-emitting device 1 provided by the present disclosure, the diffusion blocking layer 30 disposed under the first electrode 50 (N electrode) in the stacking direction may effectively prevent the diffusion of the metal materials between the first electrode 50 and the first semiconductor layer 21 from being too deep when being fused at high temperature. Meanwhile, the ohmic contact layer 40 may ensure the electrical conduction between the first electrode 50 and the first semiconductor layer 21. During the manufacturing of the light-emitting device 1, the formation of the second electrode 60 (e.g., P electrode) in the recess may reduce the height difference between the P electrode and the N electrode, which is beneficial in the die bonding or flip chip packaging of the light-emitting device 1. In addition, in the light-emitting device 1, the upper surface of the first electrode 50 being flush with the upper surface of the second electrode 60 may enhance the overall optoelectronic performance of the light-emitting device 1.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
an epitaxial structure that includes a first semiconductor layer, an active layer, and a second semiconductor layer disposed sequentially in such order;
a diffusion blocking layer that is disposed on a surface of said first semiconductor layer opposite to said active layer;
an ohmic contact layer that is disposed on a surface of said diffusion blocking layer opposite to said first semiconductor layer;
a first electrode that is disposed on a surface of said ohmic contact layer opposite to said diffusion blocking layer and that is electrically connected to said first semiconductor layer; and
a second electrode that is disposed on and electrically connected to said second semiconductor layer.

2. The light-emitting device as claimed in claim 1, further comprising an insulation layer formed on said epitaxial structure, said insulation layer having two through holes, said first electrode and said second electrode respectively extending into said through holes to electrically connect to said first semiconductor layer and said second semiconductor layer, respectively.

3. The light-emitting device as claimed in claim 2, wherein said ohmic contact layer is exposed from said insulation layer through a respective one of said through holes and is spaced apart from said insulation layer by a gap, said first electrode extending into said gap to contact said diffusion blocking layer.

4. The light-emitting device as claimed in claim 1, further comprising a supporting substrate and a bonding layer, said bonding layer being disposed between said supporting substrate and said epitaxial structure.

5. The light-emitting device as claimed in claim 1, wherein said diffusion blocking layer has a thickness ranging from 50 Å to 500 Å.

6. The light-emitting device as claimed in claim 1, wherein said diffusion blocking layer has a composition that is represented by GaxIn1-xP, and 0≤X≤1.

7. The light-emitting device as claimed in claim 1, wherein a projection of said ohmic contact layer on said epitaxial structure falls within a projection of said first electrode on said epitaxial structure.

8. The light-emitting device as claimed in claim 1, wherein each of said first electrode and said second electrode is a metal electrode.

9. The light-emitting device as claimed in claim 1, wherein an upper surface of said first electrode is flush with an upper surface of said second electrode.

10. The light-emitting device as claimed in claim 1, wherein said first electrode includes a first contact electrode and a first electrode pad formed on said first contact electrode, said second electrode includes a second contact electrode and a second electrode pad formed on said second contact electrode.

11. The light-emitting device as claimed in claim 1, wherein said light-emitting device radiates one of red light and infrared light.

12. A method for manufacturing a light-emitting device, comprising steps of:
sequentially forming an ohmic contact layer, a diffusion blocking layer, a first semiconductor layer, an active layer, and a second semiconductor layer on a growth substrate so as to form a laminate structure on said growth substrate;
bonding the laminate structure to a supporting substrate through a bonding layer with said second semiconductor layer facing said bonding layer, and removing said growth substrate;
forming an insulation layer on said ohmic contact layer and said diffusion blocking layer, said insulation layer having two through holes; and
forming a first electrode and a second electrode on said insulation layer such that said first electrode and said second electrode respectively extend into said through holes to electrically connect to said first semiconductor layer and said second semiconductor layer, respectively.

13. The method for manufacturing the light-emitting device as claimed in claim 12, wherein an upper surface of said first electrode is flush with an upper surface of said second electrode.

14. The method for manufacturing the light-emitting device as claimed in claim 12, wherein said light-emitting device radiates one of red light and infrared light.

15. The method for manufacturing the light-emitting device as claimed in claim 12, further comprising a step of, before forming said insulation layer, forming a recess in the laminate structure, said recess penetrating into said second semiconductor layer through said diffusion blocking layer, said first semiconductor layer and said active layer, said recess being in spatial communication with one of said through holes.

16. The method for manufacturing the light-emitting device as claimed in claim 12, wherein said diffusion blocking layer has a thickness ranging from 50 Å to 500 Å.

17. The method for manufacturing the light-emitting device as claimed in claim 12, wherein said diffusion blocking layer has a composition that is represented by GaₓIn₁₋ₓP, and 0≤X≤1.

18. The method for manufacturing the light-emitting device as claimed in claim 12, wherein a projection of said ohmic contact layer on said first semiconductor layer falls within a projection of said first electrode on said first semiconductor layer.

19. The method for manufacturing the light-emitting device as claimed in claim 12, wherein each of said first electrode and said second electrode is a metal electrode.

20. The method for manufacturing the light-emitting device as claimed in claim 12, wherein said first electrode includes a first contact electrode and a first electrode pad formed on said first contact electrode, said second electrode including a second contact electrode and a second electrode pad formed on said second contact electrode.
